(19) United States
(12) Patent Application Publication
(10) Pub. No.: US 2026/0022450 A1
(43) Pub. Date: Jan. 22, 2026

(54) METHOD OF OPERATING A PLASMA PROCESS SYSTEM AND A PLASMA PROCESS SYSTEM

(71) Applicant: TRUMPF HUETTINGER SP. Z O. O., Zielonka (PL)

(72) Inventors: Wojciech GAJEWSKI, Warsaw (PL); Cezary KAMINSKI, Warsaw (PL); Anna ONISZCZUK, Zielonka (PL); Piotr ROZANSKI, Wolomin (PL)

(21) Appl. No.: 19/346,588

(22) Filed: Oct. 1, 2025

Related U.S. Application Data
(63) Continuation of application No. PCT/EP2024/059074, filed on Apr. 3, 2024.

(30) Foreign Application Priority Data
Apr. 3, 2023 (EP) 23460010.4

(51) Int. Cl. C23C 14/35; C23C 14/34; H01J 37/34

(52) U.S. Cl. CPC C23C 14/352; C23C 14/3485; H01J 37/3467; H01J 2237/332

(57) ABSTRACT

A method of operating a plasma process system is provided. The plasma process system includes a plasma process chamber with a plasma process chamber wall connected to an electrical potential, a high power impulse magnetron sputtering (HiPIMS) power supply for supplying high voltage high power pulses, and an electrode inside the plasma process chamber connected to the HiPIMS power supply. The method includes, in a first supply step, supplying, by using the HiPIMS power supply, pulses of high voltage with a first potential, with a pulse-on time duration to the electrode, in a first interrupt step, disconnecting the HiPIMS power supply after the pulses for a pulse-off time duration, and in a second supply step, connecting the electrode to a second potential of an opposite sign of the first potential in relation to the plasma process chamber wall immediately before the pulses of high voltage with the first potential start.

### CROSS REFERENCE TO RELATED APPLICATIONS

This application is a continuation of International Application No. PCT/EP2024/059074 (WO 2024/208908 A1), filed on Apr. 3, 2024, and claims benefit to European Patent Application No. EP 23460010.4, filed on Apr. 3, 2023. The aforementioned applications are hereby incorporated by reference herein.

### FIELD

Embodiments of the present invention relate to a method of operating a plasma process system and a plasma process system.

### BACKGROUND

A plasma process system may be, for example, a system in which electrical power is supplied to a load, such as a plasma process arrangement.

Such a plasma process arrangement may be, for example, a plasma process chamber used for industrial plasma processes such as surface treatment of workpieces, semiconductor fabrication with plasma, or processing of workpieces with gas lasers.

In such an application, the plasma process arrangement is used to generate plasma.

To be able to generate plasma, a plasma process arrangement, e. g. a plasma process chamber, can have one or more electrodes. These electrodes can be designed as targets acting as cathodes, which can be connected to an electrical potential, especially negative electrical potential, of a DC power supply. The wall of the plasma chamber usually serves as an anode and is also connected to an electrical potential, especially ground potential.

This results in a potential difference between the target and the wall of the plasma process chamber. This potential difference is called the cathode voltage and is used to generate plasma.

The targets acting as cathodes may also have magnets that can enhance plasma generation. A power supply that has additional magnets on its acting cathode is then called a magnetron.

Target atoms are released from the target in plasma processes, which can then be used to coat a substrate located in the plasma process chamber, for example. The substrate can be connected to the wall of the plasma process chamber.

In common plasma generation processes, the DC power supply may provide power in the form of DC pulses. Characteristic of these DC pulses is that a high negative voltage is applied for a very short period of time and the DC pulses are repeated in defined time intervals. Between the DC pulses, the so-called pulse off time, the target acting as cathode is floating.

Such plasma generation techniques are called HiPIMS (high power impulse magnetron sputtering), which require suitable HiPIMS power supplies.

Such HiPIMS power supplies are disclosed and described in more detail in the following publication, e.g.: WO 2013/000918 A1.

Characteristics of HiPIMS include short pulses of a few micro- or milliseconds, a short duty cycle (on-off ratio)<10% and the high degree of ionization of the released target atoms. The average power here is very similar to conventional DC sputtering processes in which no pulses are used. The power of the pulses may be equal or larger than 10 kW, in particular equal or larger than 100 kW.

In addition, a bias voltage may be applied to the substrate in such processes. A bias voltage can be a voltage related to the wall of the plasma processing chamber, in particular negative voltage, for which another DC power supply can be used, but which does not have to provide pulses.

The bias voltage can be used to influence the energy and movement direction of the ionized target atoms impinging on the substrate.

In plasma process systems that have more than one targets acting as cathodes, the plasma can be active for the entire time of a process. Together with the operational periods when the target is floating, this leads to the accumulation of charged particles of the plasma on the target. These charged particles can change the potential of the target and thus cause arcs. These arcs can damage the plasma process chamber itself and everything in the plasma process chamber.

### SUMMARY

Embodiments of the present invention provide a method of operating a plasma process system. The plasma process system includes a plasma process chamber with a plasma process chamber wall. The plasma process chamber wall is connected to an electrical potential. The plasma process system further includes a high power impulse magnetron sputtering (HiPIMS) power supply configured for supplying high voltage high power pulses, and an electrode inside the plasma process chamber connected to the HiPIMS power supply. The method includes, in a first supply step, supplying, by using the HiPIMS power supply, pulses of high voltage with a first potential, with a pulse-on time duration to the electrode, in a first interrupt step, disconnecting the HiPIMS power supply after the pulses for a pulse-off time duration, and in a second supply step, connecting the electrode to a second potential of an opposite sign of the first potential in relation to the plasma process chamber wall immediately before the pulses of high voltage with the first potential start.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a first embodiment of a plasma process system;

FIG. 2 is a second embodiment of a plasma process system;

FIGS. 3-7 are voltage characteristics of the cathode voltage for the method of operating a plasma process system according to some embodiments;

FIG. 8 is a schematic representation of an apparatus for a plasma process with a more detailed view of the high energy pulse power source according to some embodiments;

FIG. 9 is a schematic representation of a matching circuit according to some embodiments;

FIG. 10 is a schematic representation of a pulse unit according to some embodiments;

FIG. 11 is a schematic representation of another pulse unit according to some embodiments;

FIG. 12 shows a schematic representation of a plasma process with an energy absorber circuit according to some embodiments;

FIG. 13 shows energy absorber circuit according to some embodiments; and

FIG. 14 shows a bank of switches connected in series and parallel according to some embodiments.

### DETAILED DESCRIPTION

Embodiments of the present invention provide a plasma system and a method of operating a plasma process system which mitigates arcing in a plasma process chamber.

According to embodiments of the present invention, a method of operating a plasma process system is proposed where the plasma process system comprises:
a) a plasma process chamber with a plasma process chamber wall being connected to an electrical potential, e. g. ground,
b) a HiPIMS power supply designed for supplying high voltage and high power pulses, in particular with a voltage equal or larger than 300 V, preferred equal or larger than 800 V, in particular with a power of the pulses equal or larger than 10 kW, especially equal or larger than 100 kW, preferred equal or larger than 1.000 kW, in particular with a duration of the pulse equal or shorter than 500 μs, preferably not longer than 300 μs, more preferably not longer than 100 μs, especially not longer than 20 μs, in particular with a repetition time of 200 μs to 1 s, where the repetition time is at least by the factor 5 larger than the pulse duration time,
c) an electrode inside the plasma chamber connected to the HiPIMS power supply,
   the method of operating a plasma process system comprising the steps:
i. in a first supply step the HiPIMS power supply supplying pulses of high voltage with a first potential, in particular with negative potential, in relation to the plasma process chamber wall with a pulse-on time duration to the electrode, and
ii. in a first interrupt step disconnect the HiPIMS power supply after the pulses for a pulse-off time duration, and
iii. in a second supply step connect the electrode to a second potential opposite of the first potential, in particular to a positive potential, in relation to the plasma process chamber wall immediately before the pulses of high voltage with first potential start.

This can provide a method of operating a plasma process system that can prevent or at least mitigate the accumulation of charged particles on the target of the plasma process system. Thereby, the damaging arcing can be mitigated.

The pulses of high voltage with a first potential, in particular with negative potential, in relation to the plasma process chamber may have preferably a pulse-on time duration which is much shorter than the pulse-off-time duration. In particular the pulse-on time duration is at least by a factor f smaller than the pulse-off-time duration with f=5, in particular 10, preferred 20.

In such a case the discharge of unwanted charge-ups could be very helpful to mitigate arcing.

It is important that in the second supply step the electrode is connected to the second potential immediately before the pulses of high voltage with first potential start. With ‘immediately’ is meant that the time duration between the end of the second potential and the start of the pulses with first potential is predefined in a way to be as short as technically reasonable. As it is clear that the first potential has a high energy and could damage a power supply providing the second potential, this power supply delivering the second potential must be disconnected or at least protected before the pulse with the first potential starts. On the other hand, the time duration between the end of the second potential and the start of the pulses with first potential in the first supply step should not be so long as to allow particles on the electrode to charge up again. So, as this depends also to geometry of the plasma chamber and electrode configuration, time durations ≤1 ms, especially ≤100 μs have been found to be reasonable.

Moreover, in the method of operating a plasma process system the electrode of the plasma process system can be connected the entire pulse off time to a positive potential in relation to the plasma process chamber. The connected potential can be a constant potential. The positive potential in the entire pulse off time does not allow the accumulation of positively charged particles on the electrode and thus prevents arcing at the beginning of a HiPIMS pulse with negative potential.

The positive potential in the second supply step can also be connected in short pulses. These pulses with positive potential can have a ramping pattern, e. g. linear slope or staircase-shaped. Further these pulses can have different lengths. The pulses with positive potential immediately before the HiPIMS pulses with negative potential can remove positively charged particles from the electrode and thus prevents arcing at the beginning of a HiPIMS pulse with negative potential.

In one aspect, the method of operating a plasma process system comprises the step of using an electrical low or especially non conducting target. It was found that especially due to high voltage and high discharge current HIPIMS operation on non conducting target is challenging due to accumulation of a charge-up on the target. With electrical low conducting target is meant a target with a high resistance per area, e.g. ≥100 Ω/cm².

In addition, in the method of operating a plasma process system the electrode of the plasma process system can be a target acting as cathode of HiPIMS power supply. The target can be a solid state that is suitable as an electrode and also contains the material with which, for example, the substrate is to be coated. The combination of target and electrode results in an uncomplicated setup of the plasma process system.

Furthermore, in the method of operating a plasma process system a substrate to be processed in the plasma process chamber can also be connected to the HiPIMS power supply. The substrate can also be connected to a second power supply or to both, the HiPIMS power supply and a second power supply. The substrate can also be connected only to a second power supply. The second power supply can also be a HiPIMS power supply or a conventional dc power supply, which does not supply pulses but a constant voltage.

If the substrate is connected to the HiPIMS power supply, the same voltage is applied between the substrate and the wall of the plasma process chamber as is applied between the electrode and the wall of the plasma process chamber. In this use, however, this voltage between the substrate and the wall of the plasma process chamber is not used for plasma generation, but as a so-called bias voltage.

In case the HiPIMS power supply and a second power supply are connected to the substrate, switches can be used, for example, by which the HiPIMS power supply or the second power supply can be switched on and off. This allows the voltage provided by the HiPIMS power supply or the second power supply to be switched on and off. The switches can be, for example, semiconductor switching elements such as metal oxide semiconductor field-effect transistors (MOSFETS).

If only a second power supply is connected to the substrate, a bias voltage can be supplied to the plasma process system via this second power supply.

Moreover, the method of operating a plasma process system can be used whenever the plasma process system has a suitable HiPIMS power supply. This makes the method of operating a plasma process system according to embodiments of the invention very widely applicable.

In one aspect the method comprises a step of delivering power to a second electrode in the plasma chamber by a third power supply which is different from the HIPIMS power supply.

With ‘different’ is meant here that the power supply is not of the same type, so it does not deliver HIPIMS pulses. It could be a pulsed DC power supply delivering low energy pulses to the second electrode. It could be a DC power supply delivering continuous DC power to the second electrode. It could be a MF power supply delivering bipolar rectangular or bipolar sinuous MF power, e.g., with a frequency in the range of 1 kHz to 500 kHz, to the second electrode. It could be a HF power supply delivering HF power, e.g., with a frequency in the range of 1 MHz to 200 MHz, to the second electrode.

The plasma process system according to embodiments of the invention for executing the method of operating a plasma process system comprises a plasma process chamber with a plasma process chamber wall, a HiPIMS power supply and an electrode.

The plasma process chamber wall is connected to an electrical potential, e. g. ground. The HiPIMS power supply is designed for the provision of high-voltage and high-power pulses. The electrode is connected to the HiPIMS power supply.

The electrode is located in the plasma process chamber and the pulses from the HiPIMS power supply enter the plasma process chamber via it. The electrode can be a target acting as the cathode of the HiPIMS power supply.

In an advantageous further embodiment, the plasma process system may have more than one electrode. This allows, for example, a coated substrate to have a higher wear resistance than a coated substrate in a plasma process system with a single electrode.

In one aspect the problem may be solved by a plasma process system, comprising:
a) a plasma process chamber with a plasma process chamber wall being connected to an electrical potential, e. g. ground,
b) a HiPIMS power supply designed for supplying high voltage high power pulses,
c) an electrode inside the plasma chamber connected to the HiPIMS power supply, and
the plasma process system is configured to perform the following steps:
   i. in a first supply step the HiPIMS power supply supplying pulses of high voltage with a first potential, in particular a negative potential, in relation to the plasma process chamber wall to the electrode, and
   ii. in a first interrupt step is disconnected in pulse off times, and
   iii. in a second supply step the electrode is connected to a second potential opposite of the first potential, in particular a positive potential, in relation to the plasma process chamber wall immediately before the pulses of high voltage with first potential.

In one aspect the plasma process system comprises a second electrode. This second electrode may be connected to a third power supply which is different from the HIPIMS power supply.

With ‘different’ is meant here that the power supply is not of the same type, so it is no HIPIMS power supply as it is explained earlier in this disclosure.

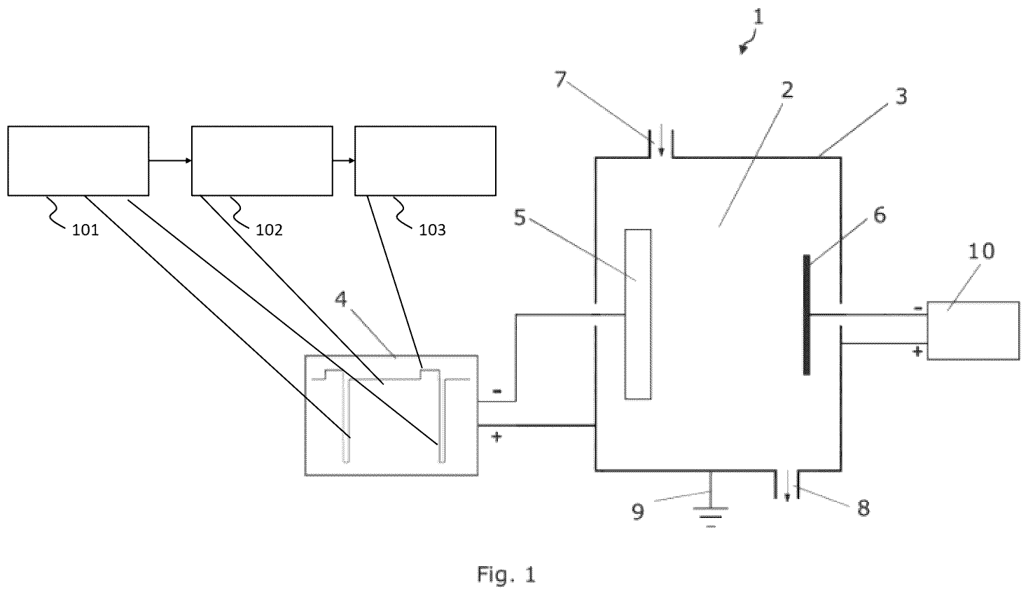

FIG. 1 shows one possible embodiment of a plasma process system 1 for the method of operating a plasma process system according to the invention. The plasma process system 1 comprises a HiPIMS power supply 4, a plasma process chamber 2, and a second power supply 10. This plasma process chamber 2 includes a wall 3, a gas inlet 7, a gas outlet 8, an electrode 5 and a substrate 6. The wall 3 of the plasma process chamber 2 is connected to ground potential 9. In this case the wall 3 of the plasma process chamber 2 forms the anode of the HiPIMS power supply 4 and of the second power supply 10.

Sputtering and reactive gas required for plasma generation can be admitted via the gas inlet 7. The sputtering gas can be argon, for example. The reactive gas can be nitrogen, for example. The gas outlet 8 is designed to create a vacuum in the plasma process chamber 2. The gas outlet 8 can also have other components for vacuum generation, such as a pump and valves. Vacuum here means a space with extensive absence of matter.

The electrode 5 is implemented in form of a target and is connected to the negative potential of the HiPIMS power supply 4 and thus forms the cathode of the HiPIMS power supply 4.

The cathode voltage is applied between the electrode 5 and the wall 3 of the plasma process chamber 2.

The bias voltage can be applied via a second power supply 10. This second power supply 10 is also connected to the substrate 6. The second power supply 10 can also be a HiPIMS power supply or a conventional dc power supply, which does not supply pulses but a constant voltage.

Plasma is generated within the plasma process chamber 2, which is used, for example, to coat the substrate 6.

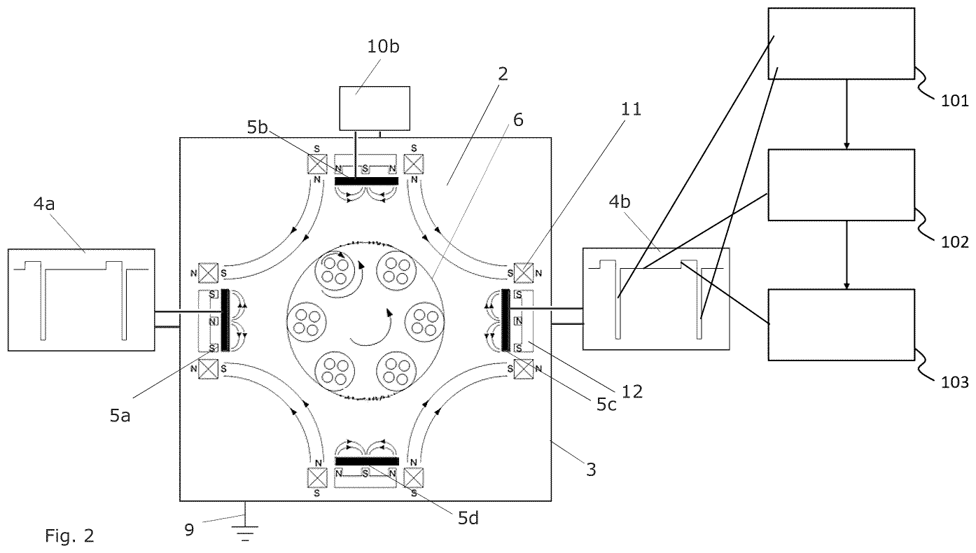

FIG. 2 shows a second embodiment of a plasma process system 1 for the method of operating a plasma process system according to the invention. The plasma process system 1 comprises also a plasma process chamber 2 with a wall 3 connected to ground 9. This plasma process chamber 2 includes also a gas inlet (not shown), a gas outlet (not shown), and a substrate 6. The substrate 6 is here build as an in several directions rotatable tool holder, where the tools are to be covered with the plasma process. This plasma process chamber 2 comprises four electrodes 5a-5d acting as cathodes and targets. Several magnets 11, 12 are placed behind the electrodes 5a-5d, all marked with their poles N and S. Those magnets are used to enhance the ionization process and could also be placed in the plasma chamber of FIG. 1. Two HiPIMS power supplies 4a, 4b, are connected to two electrodes 5a, 5c, respectively. A third electrode 5b is connected to a third power supply 10b, which is different from the HiPIMS power supplies 4a, 4b. A fourth electrode 5d may connected to a further power supply (not shown) which may be also different. With ‘different’ is meant here that the power supply is not of the same type as the HIPIMS power supply 4a, 4b as it is explained earlier in this disclosure.

Other possible embodiments of a plasma process system with a HiPIMS power supply are shown in the following publications, e.g.: WO 2013/000918 A1, US 2010/0025230 A1.

With such a plasma process system 1 as shown e.g., in FIG. 1 or 2, the following method steps are executable:
i. in a first supply step 101 the HiPIMS power supply 4 supplies a pulse of high voltage with a first potential, in particular a negative potential in relation to the plasma process chamber wall 3 with a pulse-on time duration tₒₙ to the electrode 5, and
ii. in a first interrupt step 102 the HiPIMS power supply 4 disconnects after the high voltage pulse for a pulse-off time duration t_{off}, and
iii. in a second supply step 103 the electrode 5 is connected to a second potential opposite of the first potential, in particular a positive potential, in relation to the plasma process chamber wall 3 immediately before the next pulse of high voltage with first potential starts.

A HiPIMS power supply may be designed for the provision of pulses with a voltage equal or larger than 300 V, preferred equal or larger than 800 V.

Especially, in such a case the discharge of unwanted charge-ups could be very helpful to mitigate arcing.

A HiPIMS power supply may be designed for the provision of pulses with a power of the pulses equal or larger than 10 kW, especially equal or larger than 100 kW, preferred equal or larger than 1.000 kW. Especially, in such a case the discharge of unwanted charge-ups could be very helpful to mitigate arcing.

A HiPIMS power supply may be designed for the provision of pulses with a duration of the pulse equal or shorter than 500 μs, preferably not longer than 300 μs, more preferably not longer than 100 μs, especially not longer than 20 μs, in particular with a repetition time of 200 μs to 1 s, where the repetition time is at least by the factor 5 larger than the pulse duration time. Especially, in such cases the discharge of unwanted charge-ups could be very helpful to mitigate arcing.

A HiPIMS power supply may be designed for the provision of pulses with an energy of at least 10 J. Especially, in such a case the discharge of unwanted charge-ups could be very helpful to mitigate arcing.

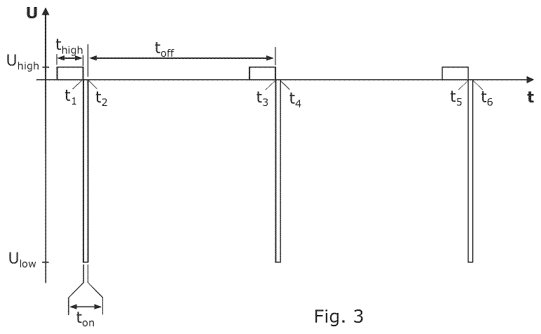

FIG. 3 to 7 show possible voltage characteristics of the cathode voltage for the method of operating a plasma process system according to the invention in diagrams, where the voltage U is shown over the time t. With “cathode voltage” is meant here the pulses provided by the HiPIMS power supply 4. The characteristic short pulses in the first supply step 101 with a first potential, in particular here with the high negative voltage, have the same pulse-on duration time tₒₙ in all figures. After a pulse off time t_{off}, the next pulse with high negative voltage starts. So, these pulses of high voltage with a first potential have a repetition time duration which is the sum of this pulse-on duration time tₒₙ and the pulse-off time duration t_{off}. The pulses with the second, in particular with the positive voltage in the second supply step 103 according to the invention differ during the pulse off time t_{off} from FIG. 3 to FIG. 6.

During the characteristic short negative pulses during the first supply step 101, the HiPIMS power supply 4 provides the cathode voltage U_{low}. Such a pulse starts at times t₁, t₃, t₅ and ends at times t₂, t₄, t₆, and has a duration of tₒₙ. Following the end of the pulses with the first interrupt step 102 at the times t₂, t₄, t₆, the pulse-off time duration t_{off} starts, during which the HiPIMS power supply 4 does not supply pulses with high negative voltage. A HiPIMS power supply 4 is usually realized by one or more energy storages, such as one or more big capacitors, which are loaded to a high energy level, and e.g. a high voltage, during the pulse-off time duration t_{off} and are discharged during the pulse-on time duration tₒₙ by switching elements. So, during the pulse-off time duration t_{off}, the electrode 5 is not connected to any potential and is therefore floating. It was found that such a floating electrode 5 tends to attract particles, ions, and/or atoms being present in the plasma chamber. These particles, ions, and/or atoms could lead to an insulating or at least bad conducting surface on the electrode or nearby. It was further found that with the start of one of the following pulses, such a surface may charge up or even been charged up by other comparable continuous plasma processes in the chamber. Such charge ups could lead to a higher arc-rate which is undesirable.

During the pulse off time t_{off}, the HiPIMS power supply 4 according to the invention may provide with the second supply step 103 a pulse with a second potential opposite of the first potential, in particular in the form of a positive cathode voltage. This pulse with the second potential may differ in shape and length and may prevent the accumulation of charged particles on the target, whereby the arcing can be mitigated.

It is important, that the pulses with the second potential opposite of the first potential during the second supply step 103 are immediately before the pulses with the first potential during the first supply step 101. With ‘immediately’ is meant that the time duration between the end of the second potential and the start of the pulses with first potential is predefined in a way to be as short as technically reasonable. As it is mentioned earlier, it is clear that the first potential has a high energy and could damage a power supply providing the second potential. This power supply providing the second potential must therefore be disconnected or at least protected before the pulse with the first potential starts. This needs at least some time. On the other hand, the time duration between the end of the second potential and the start of the pulses with first potential should not be so long as to allow particles on the electrode 5 to charge up again. So, as this depends also to geometry of the plasma chamber 2 and electrode 5 configuration, time durations ≤1 ms, especially ≤100 μs have been found to be reasonable.

As can be seen in FIG. 3 to 6, the pulses of high voltage with a first potential, in particular with negative potential, in relation to the plasma process chamber may have preferably a pulse-on time duration tₒₙ which is much shorter than the pulse-off-time duration t_{off}. In particular, the pulse-on time duration is at least by a factor f smaller than the pulse-off-time duration with f=5, in particular 10, preferred 20. Especially, in such a case the discharge of unwanted charge-ups could be very helpful to mitigate arcing.

In FIG. 3, this positive pulse has a rectangular shape of length t_{high} and the HiPIMS power supply 4 provides the cathode voltage U_{high} throughout the whole pulse. The positive pulse is applied immediately before the pulse with high negative voltage. Especially, in such a case the discharge of unwanted charge-ups could be very helpful to mitigate arcing.

In FIG. 4, the HiPIMS power supply 4 provides the positive cathode voltage U_{high} throughout the whole pulse-off time t_{off}. Especially, in such a case the discharge of unwanted charge-ups could be very helpful to mitigate arcing.

In FIG. 5, the positive pulse has a ramping pattern and a length of t_{high}. The positive pulse is located before the negative pulse at the end of the pulse off time t_{off}. The positive pulse increases linearly to the cathode voltage U_{high}. After reaching this cathode voltage U_{high}, it is kept constant until the end of the pulse-off time t_{off}. Especially, in such a case the discharge of unwanted charge-ups could be very helpful to mitigate arcing.

FIG. 6 is very similar to FIG. 5 except that here the positive pulse starts at the cathode voltage U_{high}, keeps it constant for a predefined time, and then decreases linearly to the end of the pulse-off time t_{off}. Especially, in such a case the discharge of unwanted charge-ups could be very helpful to mitigate arcing.

FIG. 7 is again very similar to FIG. 5 except that the positive pulse here does not rise linearly but in a staircase-shape. Especially, in such a case the discharge of unwanted charge-ups could be very helpful to mitigate arcing.

In addition to the pulse shapes shown, other pulse shapes or combinations of pulse shapes may also be possible for the cathode voltage.

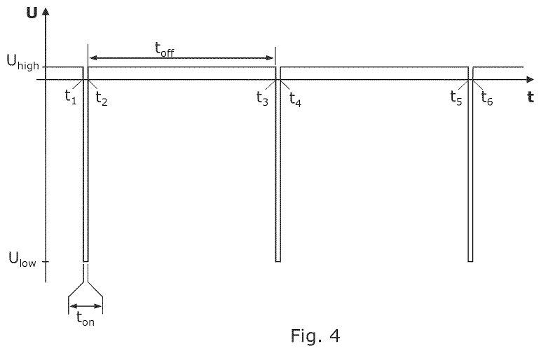

FIG. 8 shows a schematic representation of an apparatus for a plasma process, e.g., a magnetically enhanced sputtering with a more detailed view of a high energy pulse power source 40.

Such a high energy pulse power source 40 may be a HiPIMS power supply 4 or 4a as shown in the FIGS. 1 and 2 and described in this application. Such a high energy pulse power source 40 may also be a part of a HiPIMS power supply 4 or 4a as shown in the FIGS. 1 and 2 and described in this application.

The high energy pulse power source 40 has a connection to mains network via a power line and connector 41, which may be a plug. With that, it may be easily supplied with electrical energy.

The power from the mains is connected to a DC power supply 42 which is part of the high energy pulse power source 40. This may be a switch mode power supply with a transformer to disconnect the output potential from the mains potential. In such a way, the energy may be transformed very efficiently.

At the output of the DC power supply 42 a DC power is supplied via two or more power lines to a pulse unit 43, 43a. In such a way, the energy may be transferred efficiently.

The DC power supply 42 has also a communication and control line input and output, so it can be connected to the pulse unit or to an external control 39 which may be a panel or computer or to other parts. In such a way, the DC power supply 42 may be controlled effectively.

In FIG. 8 is shown a data communication line 48a between DC power supply 42 and pulse unit 43, 43a. In such a way, the DC power supply 42 and pulse unit 43, 43a may be controlled effectively.

A further data line 48c to an external control 39 is connected to the pulse unit 43, 43a. It may also be connected to the DC power supply 42. In such a way, the DC power supply 42 and pulse unit 43, 43a may be controlled effectively.

The DC power supply 42 and pulse unit 43, 43a may be placed in two separate housings. In such a way, the DC power supply 42 and pulse unit 43, 43a may be replaced in case of damage independently.

The DC power supply 42 and pulse unit 43, 43a may be placed in in one housing. In such a way, the DC power supply 42 and pulse unit 43, 43a may be controlled and arranged very effectively.

A third data communication line 48b goes from the pulse unit 43, 43a to the matching circuit 45. In such a way, the matching circuit 45 may be controlled effectively.

The matching circuit 45 is placed in the power line which goes from the pulse unit to the cathode 47 of the plasma chamber 46.

The matching circuit 45 is optional. When installed, it may give the user the possibility to dampen oscillations, to shape the current waveform in order to achieve the highly ionized plasma without going through a low ionized plasma or through an arc discharge.

To ensure the plasma process starts at every high-power pulse with the formation of a highly-ionized plasma, it is possible to monitor the plasma formation for example with a fast camera 49 which is connected to the external control 39 via a communication line 38.

As known in the art, the plasma development is dependent on a quite large number of parameters, some of which cannot be influenced by the pulse shape as it comes from the power supply. But it is possible to vary some parameters as for example the magnetic field strength and position by varying the position of the magnets. If the position of the field lines varies because of target erosion, it is possible to vary the electrical behavior of the high-power pulse via external control or via modification of the matching circuit 45.

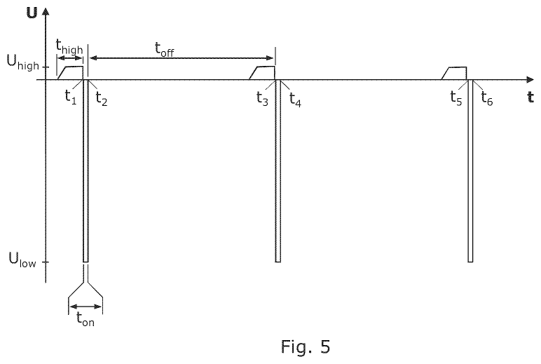

FIG. 9 shows a schematic representation of a matching circuit 45.

It includes one or several inductivity elements 53, some of them may be variable like indicated with inductivity 53a. In such a way, the matching circuit 45 may be controlled effectively.

It includes further one or more capacitors 54, some of them may be variable like indicated with capacitor 54a. In such a way, the matching circuit 45 may be controlled effectively.

It includes further one or more resistors 55, some of them may be variable like indicated with resistor 55a. In such a way, the matching circuit 45 may be controlled effectively.

Resistors, inductivities, and capacitors are replaceable. It is possible to shortcut them. This is all possible due to connection means 56. Not all connection means in FIG. 9 are referenced with a number. So, there is a big variety to shape the pulse form. In such a way, the matching circuit 45 may be controlled effectively.

The variable elements 54a, 53a, 55a may also be controlled electrically by external control. In such a way, the matching circuit 45 may be controlled effectively and fast.

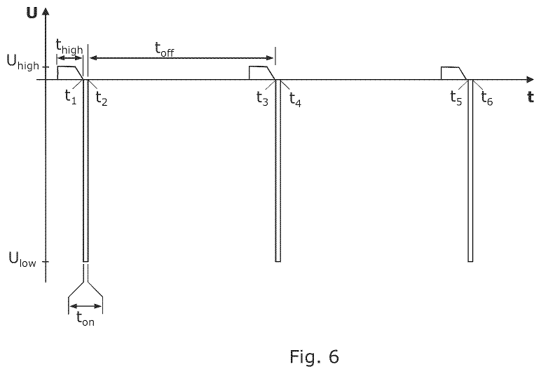

FIG. 10 shows a schematic representation of a pulse unit 43. This pulse unit 43 is arranged to build up the aforementioned pulses of high voltage with a first potential, in particular a negative potential in relation to the plasma process chamber wall 3 with a pulse-on time duration tₒₙ to the electrode 5, 5a, 5c which is here the cathode 47.

It includes a first charge current shaping unit 60 which is connected via power lines 61a, 61b to the DC power supply 42.

The first charge current shaping unit 60 delivers current via a charging diode 63 to charge a high-energy-capacitor 62.

The high-energy-capacitor 62 may be a capacitor bank of several parallel and serial connected capacitors to store enough energy for the high energy pulses.

The pulse unit 43 also includes a pulse control 65 which controls a first switch 64.

The first switch 64 closes for short controllable pulse durations of 1 μs to 300 μs.

The first switch 64 may be a bank of MOSFET switches connected in series and parallel, all switched on and off at the same time in order to lead the high-current and to switch the high-voltage of the high-energy, high-power pulse.

When the first switch 64 turns off, the current in the power lines 69a, 69b, which lead to the plasma chamber via the optional matching circuit 45, will continue to flow due to inherent inductivities, e.g. in the matching circuit and/or in the power lines.

In order to avoid destruction of the pulse unit 43, especially the first switch 64, a freewheeling diode 67 is provided between the lines 69a and 69b.

An optional current sensor 66 is included which gives a signal corresponding to the current into the plasma chamber to the pulse control 65.

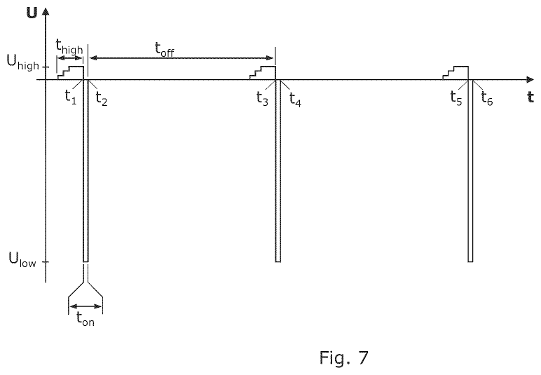

FIG. 11 shows a schematic representation of another pulse unit 43a.

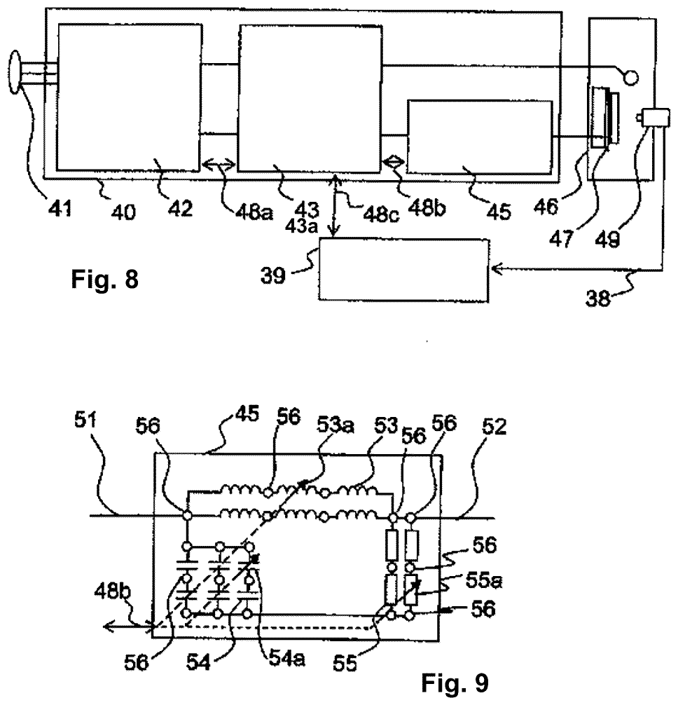

Both examples of a pulsing unit, 43 from FIG. 10, and 43a from FIG. 11, could be arranged in the high energy pulse power source 40 as shown in FIG. 8 or in FIG. 12.

The pulse unit 43a differs from the pulsing unit 43 in FIG. 10 only in a second current shaping unit 70 and a second switch 74. This second current shaping unit 70 may be connected also to the DC power supply 42 or another DC power supply which is not shown. The current shaping unit 70 is configured to supply the second potential opposite of the first potential, in particular a positive potential, in relation to the plasma process chamber wall 3.

The combination of the second current shaping unit 70 and second switch 74 is configured to perform the second supply step 103, connecting the electrode 5, 5a, 5c to a second potential opposite of the first potential, in particular a positive potential, in relation to the plasma process chamber wall 3 immediately before the pulses of high voltage with first potential start. For that, the second switch 74 is also controlled by the pulse control 65.

The embodiment of FIG. 11 is one possible example to realize the method steps as mentioned earlier all in one power supply 4 or 4a:
i. in a first supply step 101 the HiPIMS power supply 4 supplies a pulse of high voltage with a first potential, in particular a negative potential in relation to the plasma process chamber wall 3 with a pulse-on time duration tₒₙ to the electrode 5 by closing the first switch 64, and
ii. in a first interrupt step 102 the HiPIMS power supply 4 disconnects after the high voltage pulse for a pulse-off time duration t_{off} by opening the first switch 64, and
iii. in a second supply step 103 the electrode 5 is connected to a second potential opposite of the first potential, in particular a positive potential, in relation to the plasma process chamber wall 3 immediately before the next pulse of high voltage with first potential starts by closing the second switch 74.

FIG. 12 shows a schematic representation of an apparatus for a plasma process, e.g., a magnetically enhanced sputtering as shown in FIG. 8 with an additional energy absorber circuit 106.

Such a high energy pulse power source 40 may be a HiPIMS power supply 4 or 4a as shown in the FIGS. 1 and 2 and described in this application. Such a high energy pulse power source 40 may also be a part of a HiPIMS power supply 4 or 4a as shown in the FIGS. 1 and 2 and described in this application.

Also, this high energy pulse power source 40 has a data communication line 48d and is in connection with the external control 39, the pulse unit 43, 43a and the DC power supply 42. There may also be an optional data connection 48e to the matching unit 45. The additional energy absorber circuit 106 is configured to absorb the energy, at least partly, which is stored in the power lines from the high energy pulse power source 40 to the plasma chamber 46.

It may also at least partly absorb the energy which is stored in the plasma chamber 46.

This energy absorber circuit 106 is configured to be activated when a sensor such as the current sensor 66 of the pulse unit 43, 43a detects an abnormal current rise. This may be caused by an arc discharge in the plasma chamber.

When an arc discharge is detected, the first switch 64 may be opened immediately by pulse control 65. The arc then quenches in about 100 μs or less. Only the remaining energy in the power lines and matching circuit 45 is delivered to the plasma, which is often too much. To avoid even the delivery of this energy at least partly, the energy absorber circuit 106 is activated.

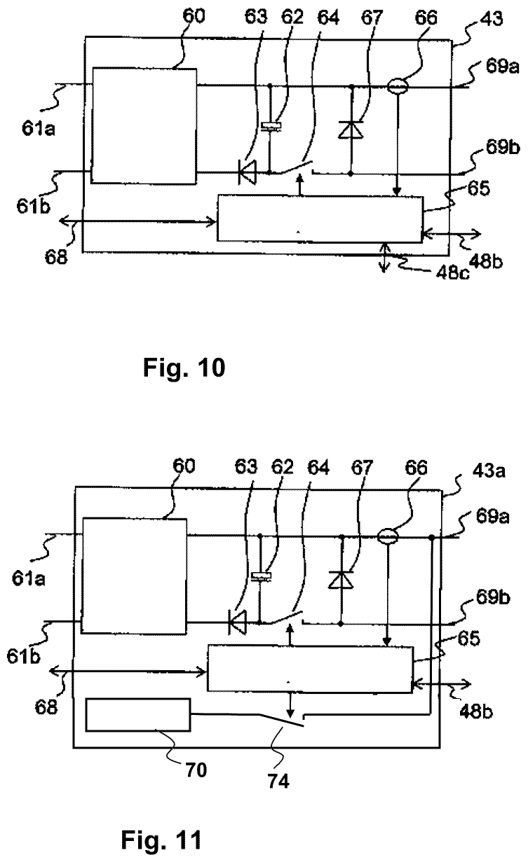

FIG. 13 shows such an energy absorber circuit 106 in more detail. A control section 113 controls a third switch 114 which is normally closed. In case of abnormal current rise or arc detection this third switch 114 opens as quickly as possible. The current which flows at this moment in the power lines between the high energy pulse power source 40 and the plasma chamber 46 keeps on flowing due to the inherent inductivity, e.g., in the power lines. The current flows now via the diode 112 into the capacitor 111. A precharging and discharging circuit 110 is connected to the capacitor 111. It precharges the capacitor 111 to a defined voltage, which helps to absorb the energy as quickly as possible. The current decreases while the capacitor 111 will be charged by the current. To avoid an overvoltage at the capacitor 111 after several activations of the energy absorber circuit 106, the capacitor 111 must be discharged. This can be done by a discharging circuit, which may be also implemented in the precharging and discharging circuit 110. The capacitor 111 may also be placed in the DC power supply and the energy which comes from the power lines into the capacitor may be used to charge the high-energy-capacitor 62 of the pulse unit 43.

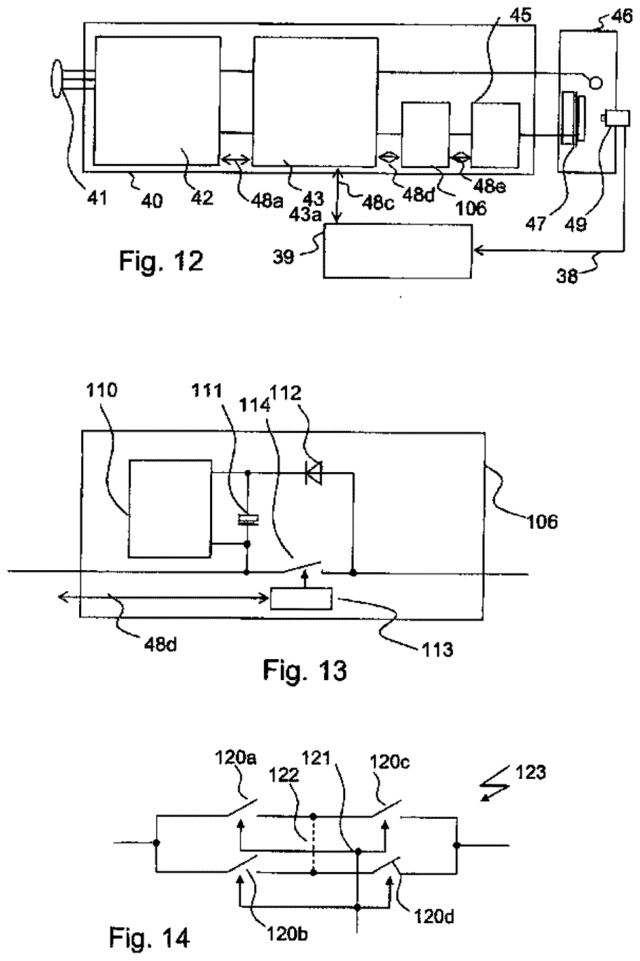

FIG. 14 shows a bank of switches 123 which comprises here four switching components 120a, 120b, 120c, 120d connected in series and parallel. This is a configuration as it may be used for the first switch 64 of the pulse unit 43, the second switch 74, or for the third switch 114 of the energy absorber circuit 106.

All four switching components 120a, 120b, 120c, 120d, which may be MOSFETs, are switched on and off at the same time. They are controlled via a control line 121. A connection 122 between both series connected switching component pairs 120a, 120c and 120b, 120d is optional.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method of operating a plasma process system, wherein the plasma process system comprises:
a plasma process chamber with a plasma process chamber wall, the plasma process chamber wall being connected to an electrical potential,
a high power impulse magnetron sputtering (HiPIMS) power supply configured for supplying high voltage high power pulses, and
an electrode inside the plasma process chamber connected to the HiPIMS power supply,
the method comprising:
in a first supply step, supplying, by using the HiPIMS power supply, pulses of high voltage with a first potential, with a pulse-on time duration to the electrode,
in a first interrupt step, disconnecting the HiPIMS power supply after the pulses for a pulse-off time duration, and
in a second supply step, connecting the electrode to a second potential of an opposite sign of the first potential in relation to the plasma process chamber wall immediately before the pulses of high voltage with the first potential start.

2. The method according to claim 1, wherein the electrode is connected to the second potential during an entirety of the pulse-off time.

3. The method according to claim 1, wherein the second potential is connected to the electrode as pulses that are shorter than the pulse-off time duration.

4. The method according to claim 3, wherein the pulses with the second potential have a ramping pattern.

5. The method according to claim 1, wherein the electrode is a target acting as a cathode.

6. The method according to claim 1, wherein a substrate to be processed is also connected to the HiPIMS power supply or a second power supply.

7. A plasma process system configured for executing the method of claim 1, the plasma process system comprising:
a plasma process chamber with a plasma process chamber wall, the plasma process chamber wall being connected to an electrical potential,
a high power impulse magnetron sputtering (HiPIMS) power supply configured for providing the high voltage high power pulses, and
an electrode connected to the HiPIMS power supply.

8. The plasma process system according to claim 7, further comprising a second electrode.

9. The plasma process system according to claim 7, wherein the second electrode is connected to a third power supply that is different from the HIPIMS power supply.

10. The plasma process system according to claim 7, wherein the electrode is configured as a target, and the target is at least partially non conducting.

11. A high power impulse magnetron sputtering (HiPIMS) power supply configured for supplying high voltage high power pulses,
the HiPIMS being configured to:
supply power to a plasma process system according to claim 7,
the HiPIMS comprising one or more of following:
a connection to a mains network via a power line and connector,
a DC power supply,
a pulse unit,
a first switch,
a second switch,
a high-energy-capacitor,
a first charge current shaping unit,
a charging diode,
a second current shaping unit, or
a matching circuit.
